(19) United States
(12) Patent Application Publication
(10) Pub. No.: US 2011/0209907 A1
(43) Pub. Date: Sep. 1, 2011

(54) LIQUID-REPELLENT FILM FORMER, METHOD FOR FORMING LIQUID-REPELLENT FILM, METHOD FOR FORMING FINE WIRING USING THE SAME, AND SUBSTRATE COMPRISING THE SAME

(75) Inventors: Jong-Hee LEE, Yongin-si (KR); Kyu-Nam Joo, Yongin-si (KR); Young-su Kim, Yongin-si (KR); Jae-Myung Kim, Yongin-si (KR)

(73) Assignee: Samsung SDI Co., Ltd., Yongin-si (KR)

(21) Appl. No.: 12/862,613

(22) Filed: Aug. 24, 2010

(30) Foreign Application Priority Data
Feb. 26, 2010 (KR) 10-20100018119

(51) Int. Cl. H05K 1/00; B05D 5/08; C09D 7/00

(52) U.S. Cl. 174/258; 427/387; 106/287.13

(57) ABSTRACT

Disclosed are a liquid-repellent film former, a method for forming a liquid-repellent film, a method for forming fine wiring based on the same, and a printed circuit board including the same. The liquid-repellent film former includes a first coupling agent including a compound represented by the following Chemical Formula 1, a second coupling agent including a compound represented by the following Chemical Formula 2, and an alcohol solvent.

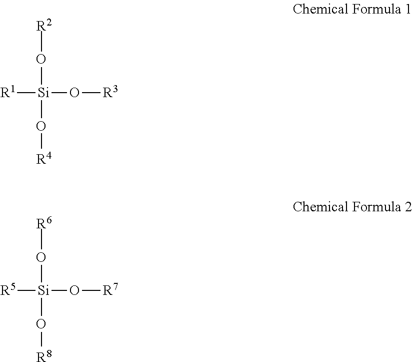

Herein, the definitions of R¹ to R⁸ are as described in the specification.

### CROSS-REFERENCE TO RELATED APPLICATIONS

This application claims priority to and the benefit of Korean Patent Application No. 10-2010-0018119 filed in the Korean Intellectual Property Office on Feb. 26, 2010, the entire contents of which are incorporated herein by reference.

### BACKGROUND

1. Field

This disclosure relates to a liquid-repellent film former, a method of forming a liquid-repellent film former, a method for forming fine wiring using the same, and a printed circuit board (PCB) including the same.

2. Description of the Related Technology

A liquid-repellent property refers to a characteristic of having a thread of connection with a hydrophobic property, which means little affinity for water, and it is observed in our daily life. For example, when a water drop falls onto a leaf of a lotus flower, the leaf does not get wet and the water drop rolls off.

This phenomenon occurs when a self-cleaning effect is induced as foreign substances accumulated on the surface of the leaf of the lotus flower are removed along with the water drop. Scientists have studied the phenomenon and found that protrusions of several to tens of micrometers are formed on the surface of the leaf of the lotus flower, and also that there are protrusions of tens to hundreds of nanometers distributed on the surface of the protrusions. They also found that the protrusions have a contact angle of more than about 140° with respect to water.

For example, air has a contact angle of about 180° with respect to water.

In the 1930s, scientists began studying the self-cleaning effect and the property that the surface does not easily adsorb contaminants, and research on the liquid-repellent surface is still underway.

As part of such research, Korean Patent Publication No. 1996-0033562 discloses “Process of Drainage Coating.”

The technology makes the surface of silicon rubber have excellent abrasion resistance, printing property, and anti-skid property and have smooth thin film by activating and reforming the surface of the silicon rubber through plasma etching to thereby acquire hydrophilicity and performing a primer (which is a material for enhancing adherence) process on the rubber surface, and coating it with a hydrophobic polyurethane coating material.

The conventional technology having the above structure has the following problems.

The target material comes to attain a hydrophobic property through diverse processes such as activation of the surface of the target material by performing a plasma etching process, performing a primer treatment on the surface of the activated target material, and coating it with a polyurethane coating material. There is a problem in that the coating thickness is not managed to be uniform in the coating process of a polyurethane coating material.

Since there is a restriction in the size of the target material to which the above methods are applied, the methods are not appropriate for a hydrophobic process of a target material having a large area, and they increase the defect rate.

Moreover, although the target material is formed of a hydrophobic material, it is necessarily to coat it with the polyurethane coating material. This increases production cost and decreases price competitiveness.

### SUMMARY

One embodiment of this disclosure provides a liquid-repellent film former and a method of forming a liquid-repellent film. Another embodiment of this disclosure provides a former for forming a liquid-repellent film for forming fine wiring on a substrate, a method for forming fine wiring by using a method of forming a liquid-repellent film, and a printed circuit board (PCB) including the same.

Another embodiment of this disclosure provides a liquid-repellent film former including a first coupling agent including a compound represented by the following Chemical Formula 1, a second coupling agent including a compound represented by the following Chemical Formula 2, and an alcohol solvent.

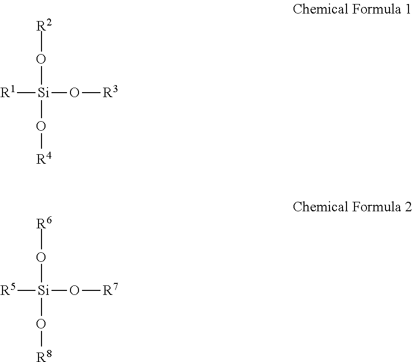

In the above Chemical Formula 1, R¹ to R⁴ are the same or different and are independently substituted or unsubstituted C1 to C6 alkyl groups, and in the above Chemical Formula 2, R⁵ is a C1 to C6 alkyl group substituted with at least one fluorine (F), and R⁶ to R⁸ are the same or different and are independently substituted or unsubstituted C1 to C6 alkyl groups.

In another embodiment, R¹ to R⁴ are the same or different, and may be independently selected from the group consisting of methyl, ethyl, propyl, and isopropyl.

In one embodiment, R⁵ may be selected from the group consisting of methyl, ethyl, propyl, and isopropyl substituted with at least one fluorine (F), and R⁶ to R⁸ are the same or different, and may be independently selected from the group consisting of methyl, ethyl, propyl, and isopropyl.

In another embodiment, the mixing ratio of the first coupling agent and the second coupling agent may range from about 1:1 to about 1:30 in weight ratio.

In another embodiment, the concentration of the mixture of the first coupling agent and the second coupling agent may range from about 0.1 to about 5 wt %, when the entire solution is 100 wt %.

In another embodiment, the alcohol solvent may be at least one selected from the group consisting of methanol, ethanol, propyl alcohol, and isopropyl alcohol.

Another embodiment of this disclosure provides a method for forming a liquid-repellent film which includes preparing a substrate, coating the substrate with a liquid-repellent film former including a first coupling agent containing a compound represented by the following Chemical Formula 1, a second coupling agent containing a compound represented by the following Chemical Formula 2, and an alcohol solvent, and drying the substrate coated with the liquid-repellent film former.

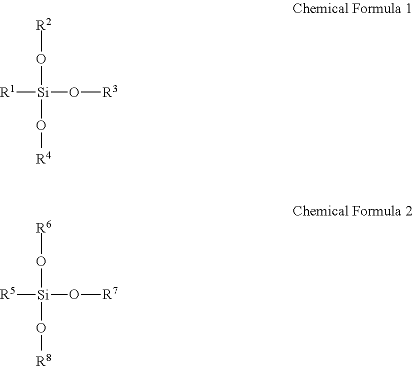

In the above Chemical Formula 1, R¹ to R⁴ are the same or different and are independently substituted or unsubstituted C1 to C6 alkyl groups, and in the above Chemical Formula 2, R⁵ is a C1 to C6 alkyl group substituted with at least one fluorine (F), and R⁶ to R⁸ are the same or different and are independently substituted or unsubstituted C1 to C6 alkyl groups.

In another embodiment, R¹ to R⁴ are the same or different, and may be independently selected from the group consisting of methyl, ethyl, propyl, and isopropyl.

In another embodiment, R⁵ may be selected from the group consisting of methyl, ethyl, propyl, and isopropyl substituted with at least one fluorine (F), and R⁶ to R⁸ are the same or different, and may be independently selected from the group consisting of methyl, ethyl, propyl, and isopropyl.

In another embodiment, the mixing ratio of the first coupling agent and the second coupling agent may range from about 1:1 to about 1:30 by weight ratio.

In another embodiment, the concentration of the mixture of the first coupling agent and the second coupling agent may range from about 0.1 to about 5 wt % when the entire solution is 100 wt %.

In another embodiment, the alcohol solvent may be at least one selected from the group consisting of methanol, ethanol, propyl alcohol, and isopropyl alcohol.

Another embodiment of this disclosure provides a method for forming fine wiring, which includes discharging a high-concentration conductive ink onto a substrate with a liquid-repellent film formed thereon through the above-described method by performing an ink jetting process.

In another embodiment, a solvent of the high-concentration conductive ink may be at least one selected from the group consisting of hexane, octane, decane, dodecane, tetradecane, and hexadecane.

Another embodiment of this disclosure provides a liquid-repellent film including a first coupling agent containing a compound represented by the following Chemical Formula 1 and a second coupling agent containing a compound represented by the following Chemical Formula 2, and a liquid-repellent film and a printed circuit board (PCB) including fine wiring formed on the liquid-repellent film.

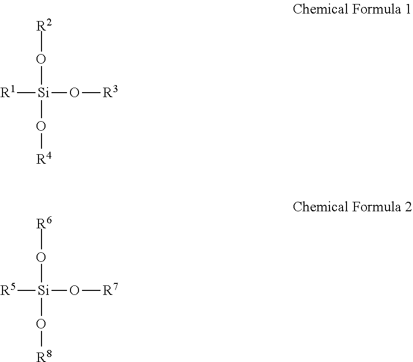

In the above Chemical Formula 1, R¹ to R⁴ are the same or different and are independently substituted or unsubstituted C1 to C6 alkyl groups, and in the above Chemical Formula 2, R⁵ is a C1 to C6 alkyl group substituted with at least one fluorine (F), and R⁶ to R⁸ are the same or different, and are independently substituted or unsubstituted C1 to C6 alkyl groups.

In another embodiment, R¹ to R⁴ are the same or different, and may be independently selected from the group consisting of methyl, ethyl, propyl, and isopropyl.

In another embodiment, R⁵ may be selected from the group consisting of methyl, ethyl, propyl, and isopropyl substituted with at least one fluorine (F), and R⁶ to R⁸ are the same or different, and may be independently selected from the group consisting of methyl, ethyl, propyl, and isopropyl.

In another embodiment, a mixing ratio of the first coupling agent and the second coupling agent may range from about 1:1 to about 1:30 by weight ratio.

In another embodiment, the fine wiring formed on the liquid-repellent film may be formed by performing an ink-jetting process.

Embodiments of this disclosure provide a liquid-repellent film former and a method for forming a liquid-repellent film to thereby form fine wiring on a substrate.

### BRIEF DESCRIPTION OF THE DRAWINGS

FIG. 1 is a schematic diagram describing a contact angle formed between the surface of a substrate and a solution.

### DETAILED DESCRIPTION

Exemplary embodiments of this disclosure will be described more fully hereinafter with reference to the accompanying drawings, in which exemplary embodiments of this disclosure are shown. As those skilled in the art would realize, the described embodiments may be modified in various different ways, all without departing from the spirit or scope of this disclosure.

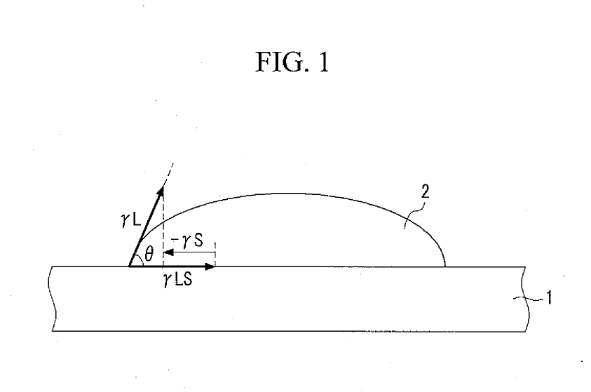

The term “contact angle” used in the present specification is defined as follows: in general, a bell-shaped solution (referring to FIG. 1) (liquid droplet, 2) existing on the surface of a substrate 1 may be defined by a contact angle (θ). The following Equation 1 (Young's equation) is realized between a contact angle (θ), the surface tension (γ L) of a solution, and the surface energy (γ S) of the substrate. In Equation 1, γ LS is an interface energy between the surface of the substrate 1 and a solution 2.

cos θ=(γS−γLS)/γL Equation 1

γ LS is decreased along with decreasing γ S, and it is generally known that when γ S is decreased, the decrease amount of γ LS is smaller than that of γ S (e.g., D. T. Kaelble, J. Adhesion, vol. 2 1970, p. 66-81). Therefore, when the surface energy γ S of the substrate 1 is decreased, the value of the right side in Equation 1 is decreased, and the contact angle (θ) is increased. Thus, a solution 2 discharged onto the surface of the substrate 1 contracts as time passes. Equation 1 may be represented by the vector shown in FIG. 1.

In order to apply an ink jetting method to an electrode of a liquid crystal display (LCD) and a plasma display panel (PDP) where electrical resistance is considered important, ink including a high-concentration conductive material is required. When the concentration of a conductive material is low, a stacking process by repeating a printing process several times in order to realize a required thickness is required, and production speed may be decreased and quality deterioration may be expected due to the repeated printing process.

As for the high-concentration conductive ink, a non-polar solvent mostly comprising hydrocarbon is selected. With the high-concentration conductive ink using non-polar hydrocarbon as a solvent and the method of treating the surface of a printed circuit board with a typical liquid-repellent agent, it is hard to acquire the contact angle, which is a criterion for evaluating a liquid-repellent property, in a satisfactory thickness.

One embodiment of this disclosure provides a liquid-repellent film former including a first coupling agent containing a compound represented by the following Chemical Formula 1, a second coupling agent containing a compound represented by the following Chemical Formula 2, and an alcohol solvent, instead of the conventional liquid-repellent agent.

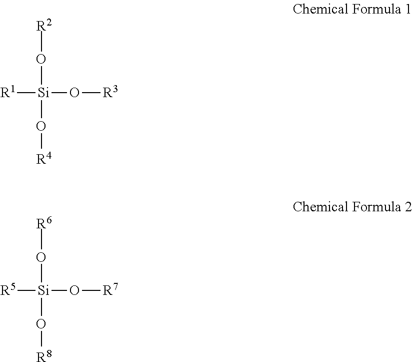

In the above Chemical Formula 1, R¹ to R⁴ are the same or different and are independently substituted or unsubstituted C₁ to C₆ alkyl groups, and in the above Chemical Formula 2, R⁵ is a C¹ to C⁶ alkyl group substituted with at least one fluorine (F) atom, and R⁶ to R⁸ are the same or different, and are independently substituted or unsubstituted C₁ to C₆ alkyl groups.

With a liquid-repellent film former including a heterogeneous silane-based coupling agent including an alkyl group and a fluorine group, it is possible to form the contact angle of the ink within a range of about 30 to about 50° although the high-concentration conductive ink is discharged onto a substrate. Thus, fine wiring may be formed on the substrate.

There is no restriction to the kind of the substrate that may be used, and substrates such as glass, plastic, and metal substrates may be used. According to one embodiment, a glass substrate may be used.

Hereafter, an example of using a glass substrate will be used. Since the glass substrate has a silanol (—SiOH) group on the surface, it has surface tension of more than about 200 mN/m.

Non-limiting examples of a solvent used for the high-concentration conductive ink include hexane, octane, decane, dodecane, tetradecane, and hexadecane. Hereafter, an example of using tetradecane will be described.

In order to widen the contact angle by discharging the high-concentration conductive ink onto a glass substrate, the threshold surface tension should be decreased to lower than the surface tension of the solvent. This is because the surface becomes hardly wet by a liquid and eventually increases the contact angle only when the threshold surface tension, which is a physical property value indicating wetness of a liquid, is decreased.

When the solvent is discharged after the liquid-repellent film is formed on the substrate by using the liquid-repellent film former including the first coupling agent, the contact angle becomes about 35° maximally and the thickness of the wiring formed by the discharging of the conductive ink becomes thin.

When the solvent is discharged after the liquid-repellent film is formed on the glass substrate by using a liquid-repellent film former including only the second coupling agent, a contact angle of greater than about 60° is formed and thus there is a problem in the adherence of the ink.

Therefore, when the first coupling agent and the second coupling agent are mixed and used as suggested in the embodiment of this disclosure, the contact angle of the solvent is adjusted within the range of about 30 to about 50° and simultaneously adherence may be secured. The line width and the thickness of the wiring may be freely controlled.

Also, since a silane coupling agent having a short main chain such as the compounds represented by Chemical Formulae 1 and 2 is decomposed by heat at a low temperature, the problem of an increased resistance value of wiring caused by residue materials may be resolved from the source.

The mixing ratio of the first coupling agent and the second coupling agent may be from about 1:1 to about 1:30 by weight ratio. When the mixing ratio exceeds 1:30, the contact angle for the non-polar solvent is not formed to be greater than about 50°. Thus, the mixing ratio may be controlled within the range of less than about 1:30.

Also, the concentration of the mixture of the first coupling agent and the second coupling agent may be from about 0.1 to about 5 wt %, when the entire solution is 100 wt %. When the concentration of the mixture is lower than about 0.1 wt %, the liquid-repellent property hardly appears, and when the concentration of the mixture exceeds about 5 wt %, the contact angle is not remarkably increased. Therefore, it is desirable to process the surface of the substrate within the above range.

R¹ to R⁴ are the same or different, and they may be independently selected from the group consisting of methyl, ethyl, propyl, and isopropyl.

Also, R⁵ may be selected from the group consisting of methyl, ethyl, propyl, and isopropyl substituted with at least one fluorine (F), and R⁶ to R⁸ are the same or different and they may be independently selected from the group consisting of methyl, ethyl, propyl, and isopropyl.

The kinds of the substituents may be selected according to the range of the effect that is desired to be acquired.

The alcohol solvent may be at least one selected from the group consisting of methanol, ethanol, propyl alcohol, and isopropyl alcohol.

Another embodiment of the this disclosure provides a method for forming a liquid-repellent film, which includes preparing a substrate, coating the substrate with a liquid-repellent film former, which includes a first coupling agent containing a compound represented by the following Chemical Formula 1, a second coupling agent containing a compound represented by the following Chemical Formula 2, and an alcohol solvent, and drying the substrate coated with the liquid-repellent film former.

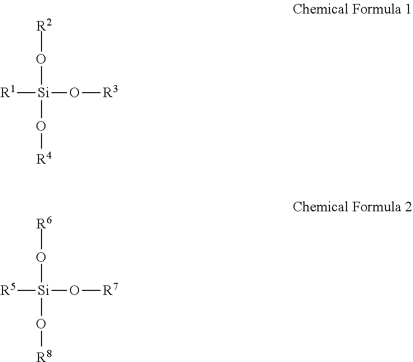

In the above Chemical Formula 1, R¹ to R⁴ are the same or different and are independently substituted or unsubstituted C₁ to C₆ alkyl groups, and in the above Chemical Formula 2, R⁵ is a C₁ to C₆ alkyl group substituted with at least one fluorine (F), and R⁶ to R⁸ are the same or different and are independently substituted or unsubstituted C₁ to C₆ alkyl groups.

R¹ to R⁴ are the same or different, and they may be independently selected from the group consisting of methyl, ethyl, propyl, and isopropyl.

R⁵ may be selected from the group consisting of methyl, ethyl, propyl, and isopropyl substituted with at least one fluorine (F), and R⁶ to R⁸ are the same or different and they may be independently selected from the group consisting of methyl, ethyl, propyl, and isopropyl.

The mixing ratio of the first coupling agent and the second coupling agent may range from about 1:1 to about 1:30 by weight ratio.

The concentration of the mixture of the first coupling agent and the second coupling agent may range from about 0.1 to about 5 wt %, when the entire solution is 100 wt %.

The alcohol solvent may be at least one selected from the group consisting of methanol, ethanol, propyl alcohol, and isopropyl alcohol.

Also, another embodiment of this disclosure provides a method for forming fine wiring, the method including discharging a high-concentration conductive ink onto a substrate with a liquid-repellent film formed thereon through the above-described method by performing an ink-jetting process.

According to the fine wiring process, the contact angle of the ink discharged onto the substrate may range from about 30° to about 50°. The width and thickness of the wiring may be freely controlled based on the contact angle.

The solvent for the high-concentration conductive ink may be at least one selected from the group consisting of hexane, octane, decane, dodecane, tetradecane, and hexadecane. Solvents that may include a conductive material at a high concentration may be generally used as the solvent.

Another embodiment of this disclosure provides a printed circuit board including a substrate, a liquid-repellent film that is formed on the substrate and includes a first coupling agent containing a compound represented by the following Chemical Formula 1 and a second coupling agent containing a compound represented by the following Chemical Formula 2, and fine wiring formed on the liquid-repellent film.

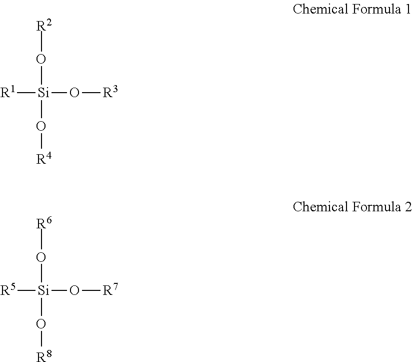

In the above Chemical Formula 1, R¹ to R⁴ are the same or different and are independently substituted or unsubstituted C₁ to C₆ alkyl groups, and in the above Chemical Formula 2, R⁵ is a C₁ to C₆ alkyl group substituted with at least one fluorine (F), and R⁶ to R⁸ are the same or different and are independently substituted or unsubstituted C₁ to C₆ alkyl groups.

R¹ to R⁴ are the same or different, and may be independently selected from the group consisting of methyl, ethyl, propyl, and isopropyl.

Also, R⁵ may be selected from the group consisting of methyl, ethyl, propyl, and isopropyl substituted with at least one fluorine (F), and R⁶ to R⁸ are the same or different, and may be independently selected from the group consisting of methyl, ethyl, propyl, and isopropyl.

Description of the substituents will be omitted herein because it is the same as previously described.

The mixing ratio of the first coupling agent and the second coupling agent may range from about 1:1 to about 1:30 by weight ratio. Description of the mixing ratio will be omitted herein because it is the same as previously described.

The fine wiring formed on the liquid-repellent film may be formed by performing an ink jetting process. The wiring of a printed circuit board (PCB) including the liquid-repellent film by performing the ink-jetting process is advantageous in terms of production cost, process simplification, low resistance, and improvement in the adherence of an electrode to a substrate.

Hereafter, examples and comparative examples of this disclosure will be described. The following examples are not more than exemplary embodiments of this disclosure, and the scope and spirit of this disclosure are not limited to the following examples.

### EXAMPLES

### Example 1

Liquid-repellent film formers are prepared by adding 1.5 g of methyl trimethoxy silane and 1.5 g of perfluoro trimethoxy silane to 100 g of isopropyl alcohol, and mixing and diluting the mixture in such a manner that the concentration of methyl trimethoxy silane and perfluoro trimethoxy silane is 0.5, 1.0, and 2.0 wt %, individually, when the entire solution is 100 wt %.

Glass substrates are respectively coated with the liquid-repellent film formers, wiped, and dried by blowing air at room temperature to thereby form liquid-repellent films for a non-polar solvent. 20 μl of tetradecane is dripped onto each of the glass substrates obtained after the process, and the contact angle for each concentration level is measured using a contact angle measurer. The measured contact angles range from about 36 to about 37°, as shown in the following Table 1.

The structure of methyl trimethoxy silane is as shown in the following Chemical Formula 3, and the structure of perfluoro trimethoxy silane is as shown in the following Chemical Formula 4.

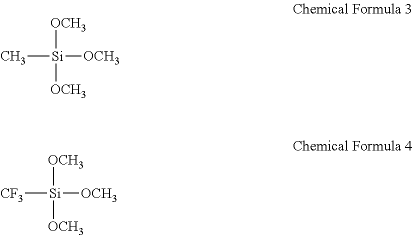

### Example 2

Liquid-repellent film formers are prepared by adding 1.5 g of methyl trimethoxy silane and 15.0 g of perfluoro trimethoxy silane to 100 g of isopropyl alcohol, and mixing and diluting the mixture in such a manner that the concentration of methyl trimethoxy silane and perfluoro trimethoxy silane is 0.5, 1.0, and 2.0 wt %, individually, when the entire solution is 100 wt %.

Glass substrates are respectively coated with the liquid-repellent film formers, wiped, and dried by blowing air at room temperature to thereby form liquid-repellent films for a non-polar solvent. 20 μl of tetradecane is dripped onto each of the glass substrates obtained after the process, and the contact angle for each concentration level is measured using a contact angle measurer. The measured contact angles range from about 41 to about 42°, as shown in the following Table 1.

### Example 3

Liquid-repellent film formers are prepared by adding 1.5 g of methyl trimethoxy silane and 1.5 g of perfluoro trimethoxy silane to 100 g of isopropyl alcohol, and mixing and diluting the mixture in such a manner that the concentration of methyl trimethoxy silane and perfluoro trimethoxy silane is 0.5, 1.0, and 2.0 wt %, individually, when the entire solution is 100 wt %.

Glass substrates are respectively coated with the liquid-repellent film formers, wiped, and dried by blowing air at room temperature to thereby form liquid-repellent films for a non-polar solvent. 20 μl of tetradecane is dripped onto each of the glass substrates obtained after the process, and the contact angle for each concentration level is measured using a contact angle measurer. The measured contact angles range from about 44 to about 45°, as shown in the following Table 1.

### Example 4

Liquid-repellent film formers are prepared by adding 1.5 g of methyl trimethoxy silane and 45.0 g of perfluoro trimethoxy silane to 100 g of isopropyl alcohol, and mixing and diluting the mixture in such a manner that the concentration of methyl trimethoxy silane and perfluoro trimethoxy silane is 0.5, 1.0, and 2.0 wt %, individually, when the entire solution is 100 wt %.

Glass substrates are respectively coated with the liquid-repellent film formers, wiped, and dried by blowing air at room temperature to thereby form liquid-repellent films for a non-polar solvent. 20 μl of tetradecane is dripped onto each of the glass substrates obtained after the process, and the contact angle for each concentration level is measured using a contact angle measurer. The measured contact angles range from about 47 to about 49°, as shown in the following Table 1.

### Comparative Example 1

Liquid-repellent film formers are prepared by adding 46.5 g of methyl trimethoxy silane to 100 g of isopropyl alcohol, and mixing and diluting the mixture in such a manner that the concentration of methyl trimethoxy silane is 0.5, 1.0, and 2.0 wt %, individually, when the entire solution is 100 wt %.

Glass substrates are respectively coated with the liquid-repellent film formers, wiped, and dried by blowing air at room temperature to thereby form liquid-repellent films for a non-polar solvent. 20 μl of tetradecane is dripped onto each of the glass substrates obtained after the process, and the contact angle for each concentration level is measured using a contact angle measurer. The measured contact angles range from about 36 to about 37°, as shown in the following Table 1.

TABLE 1

| | Mixing ratio of methyl | Concentration of | |
|---|---|---|---|
| | trimethoxy silane:perfluoro | surface treatment | Contact |
| | trimethoxy silane | agent (wt %) | angle (°) |
| Example 1 | 1:1 | 0.5 | 36 |
| | | 1.0 | 37 |
| | | 2.0 | 37 |
| Example 2 | 1:10 | 0.5 | 41 |
| | | 1.0 | 42 |
| | | 2.0 | 42 |
| Example 3 | 1:20 | 0.5 | 44 |
| | | 1.0 | 45 |
| | | 2.0 | 45 |
| Example 4 | 1:30 | 0.5 | 47 |
| | | 1.0 | 49 |
| | | 2.0 | 48 |
| Comparative | 1:0 | 0.5 | 15 |
| Example 1 | | 1.0 | 17 |
| | | 2.0 | 17 |

As shown in Table 1, the liquid-repellent film formed according to one embodiment provides a contact angle that may allow the fine wiring to be formed by using an ink-jetting method.

While this disclosure has been described in connection with what is presently considered to be practical exemplary embodiments, it is to be understood that the embodiments are not limited to the disclosed embodiments, but, on the contrary, is intended to cover various modifications and equivalent arrangements included within the spirit and scope of the appended claims. The exemplary embodiments described above are not restrictive, but are illustrative in all terms.

What is claimed is:

1. A liquid-repellent film former, comprising:
a first coupling agent including a compound represented by the following Chemical Formula 1;
a second coupling agent including a compound represented by the following Chemical Formula 2; and
an alcohol solvent: 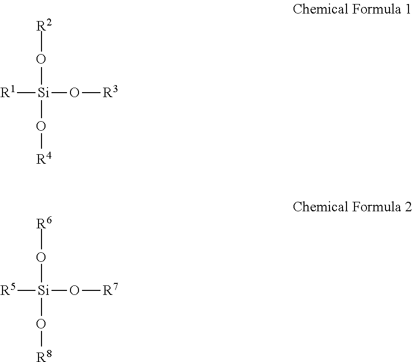
wherein, in the above Chemical Formula 1,
R¹ to R⁴ are the same or different and are independently substituted or unsubstituted C₁ to C₆ alkyl groups, and
in the above Chemical Formula 2,
R⁵ is a C₁ to C₆ alkyl group substituted with at least one fluorine (F), and
R⁶ to R⁸ are the same or different, and are independently substituted or unsubstituted C₁ to C₆ alkyl groups.

2. The liquid-repellent film former of claim 1, wherein R¹ to R⁴ are the same or different, and are independently selected from the group consisting of methyl, ethyl, propyl, and isopropyl.

3. The liquid-repellent film former of claim 1, wherein R⁵ is selected from the group consisting of methyl, ethyl, propyl, and isopropyl substituted with at least one fluorine (F), and
R⁶ to R⁸ are the same or different, and are independently selected from the group consisting of methyl, ethyl, propyl, and isopropyl.

4. The liquid-repellent film former of claim 1, wherein a mixing ratio of the first coupling agent and the second coupling agent is from about 1:1 to about 1:30 by weight ratio.

5. The liquid-repellent film former of claim 1, wherein a concentration of the mixture of the first coupling agent and the second coupling agent is from about 0.1 to about 5 wt %, when the entire solution is 100 wt %.

6. The liquid-repellent film former of claim 1, wherein the alcohol solvent is at least one selected from the group consisting of methanol, ethanol, propyl alcohol, and isopropyl alcohol.

7. A method for forming a liquid-repellent film, comprising:
preparing a substrate;
coating the substrate with a liquid-repellent film former that includes a first coupling agent containing a compound represented by the following Chemical Formula 1, a second coupling agent containing a compound represented by the following Chemical Formula 2, and an alcohol solvent; and
drying the substrate coated with the liquid-repellent film former 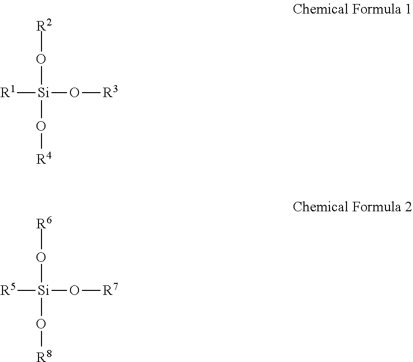
wherein, in the above Chemical Formula 1,
R¹ to R⁴ are the same or different and are independently substituted or unsubstituted C₁ to C₆ alkyl groups, and
in the above Chemical Formula 2,
R⁵ is a C₁ to C₆ alkyl group substituted with at least one fluorine (F), and
R⁶ to R⁸ are the same or different, and are independently substituted or unsubstituted C₁ to C₆ alkyl groups.

8. The method of claim 7, wherein R¹ to R⁴ are the same or different, and are independently selected from the group consisting of methyl, ethyl, propyl, and isopropyl.

9. The method of claim 7, wherein R⁵ is selected from the group consisting of methyl, ethyl, propyl, and isopropyl substituted with at least one fluorine (F), and
R⁶ to R⁸ are the same or different, and are independently selected from the group consisting of methyl, ethyl, propyl, and isopropyl.

10. The method of claim 7, wherein a mixing ratio of the first coupling agent and the second coupling agent is from about 1:1 to about 1:30 by weight ratio.

11. The method of claim 7, wherein a concentration of the mixture of the first coupling agent and the second coupling agent is from about 0.1 to about 5 wt %, when the entire solution is 100 wt %.

12. The method of claim 7, wherein the alcohol solvent is at least one selected from the group consisting of methanol, ethanol, propyl alcohol, and isopropyl alcohol.

13. A method for forming fine wiring, comprising
discharging a high-concentration conductive ink by performing an ink-jetting process on a surface with the liquid-repellent film formed thereon through the method of claim 7.

14. The method of claim 13, wherein the high-concentration conductive ink is at least one selected from the group consisting of hexane, octane, decane, dodecane, tetradecane, and hexadecane.

15. A printed circuit board (PCB), comprising:
a substrate;
a liquid-repellent film that includes a first coupling agent containing a compound represented by the following Chemical Formula 1 and a second coupling agent containing a compound represented by the following Chemical Formula 2; and
fine wiring formed on the liquid-repellent film: 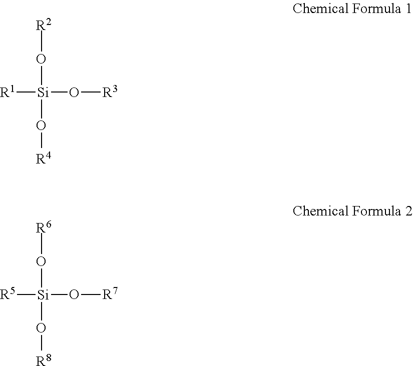
wherein, in the above Chemical Formula 1,
R¹ to R⁴ are the same or different and are independently substituted or unsubstituted C₁ to C₆ alkyl groups, and
in the above Chemical Formula 2,
R⁵ is a C₁ to C₆ alkyl group substituted with at least one fluorine (F), and
R⁶ to R⁸ are the same or different, and are independently substituted or unsubstituted C₁ to C₆ alkyl groups.

16. The printed circuit board of claim 15, wherein R¹ to R⁴ are the same or different, and are independently selected from the group consisting of methyl, ethyl, propyl, and isopropyl.

17. The printed circuit board of claim 15, wherein R⁵ is selected from the group consisting of methyl, ethyl, propyl, and isopropyl substituted with at least one fluorine (F), and
R⁶ to R⁸ are the same or different, and are independently selected from the group consisting of methyl, ethyl, propyl, and isopropyl.

18. The printed circuit board of claim 15, wherein the mixing ratio of the first coupling agent and the second coupling agent is from about 1:1 to about 1:30 by weight ratio.

19. The printed circuit board of claim 15, wherein the fine wiring formed on the liquid-repellent film is formed by performing an ink-jetting process.
